(19) United States
(12) Patent Application Publication
(10) Pub. No.: US 2011/0064877 A1
(43) Pub. Date: Mar. 17, 2011

(54) GAS SUPPLY DEVICE, VACUUM PROCESSING APPARATUS AND METHOD OF PRODUCING ELECTRONIC DEVICE

(75) Inventors: Yasuharu Matsumura, Kawasaki-shi (JP); Takayuki Moriwaki, Kawasaki-shi (JP)

(73) Assignee: CANON ANELVA CORPORATION, Kawasaki-shi (JP)

(21) Appl. No.: 12/993,168

(22) PCT Filed: Dec. 24, 2009
(86) PCT No.: PCT/JP2009/007188

§ 371 Date: Nov. 17, 2010

(30) Foreign Application Priority Data
Dec. 26, 2008 (JP) 2008-332856

(51) Int. Cl. C23C 16/455

(52) U.S. Cl. 427/248.1; 118/715

(57) ABSTRACT

To provide a gas supply device 20 which can supply a gas uniformly even if an overall length of a gas supply pipe 21 is long and can secure uniformity in film quality.

The gas supply device 20 is provided with a gas supply pipe 21 which is configured of a double-layer pipe comprising an inner pipe 23 connected to a gas introduction pipe 22 and an outer pipe 24 for covering the outer peripheral portion of the inner pipe 23 with a gap between them, wherein the inner pipe 23 has a porous sintered body 25 for allowing the passage of the gas in at least a part of it; and the outer pipe 24 has a large number of gas outlet ports 26 for discharging the gas having passed through the sintered body 25 into the vacuum vessel.

### TECHNICAL FIELD

The present invention relates to a gas supply device used to introduce a processing gas into a vacuum vessel, a vacuum processing apparatus having the gas supply device in the vacuum vessel and a method of producing an electronic device using the vacuum processing apparatus.

### BACKGROUND ART

In a case where a substrate or the like is undergone film forming processing such as sputtering, vapor deposition, ion plating and plasma polymerization within a vacuum vessel, it is necessary to supply a processing gas into the vacuum vessel. Especially, it is important for a film forming method, which forms a thin film on a substrate by supplying the reactive gas under vacuum atmosphere, to supply uniformly the reactive gas in order to keep uniformity in film quality.

As technology of uniformly supplying the reactive gas, there is proposed, for example, sputtering technology using a gas supply pipe formed with a large number of gas outflow ports in a vacuum vessel (see Patent Reference 1).

### PRIOR ART

### [Patent Reference]

[Patent Reference 1] Japanese Patent Laid-Open No. 3-166366 (FIG. 1, FIG. 2)

### DISCLOSURE OF INVENTION

### [Problems to be Solved by the Invention]

But, when a large number of gas outflow ports are simply formed in the gas supply pipe as in Patent Reference 1, provision of uniform gas within the vacuum vessel is not satisfactory. Especially, an overall length of the gas supply pipe tends to become long because of a demand for a substrate having a larger area, and there was a problem that the gas cannot be supplied uniformly because of a difference in gas flow rate between portions near to and far from a connection with the gas introducing system.

In view of the above circumstances, the present invention provides a gas supply device which can supply the gas uniformly even if the overall length of the gas supply pipe is long and can secure uniformity in film quality, a vacuum processing apparatus provided with the gas supply device and a method of producing an electronic device using the vacuum processing apparatus.

### [Means for Solving the Problem]

The structure of the invention made to achieve the above objects is as follows.

Specifically, a gas supply device according to the invention is provided with a gas supply pipe for supplying a processing gas into a vacuum vessel, wherein the gas supply pipe is a double-layer pipe comprising an inner pipe connected to a gas introduction pipe and an outer pipe for covering the peripheral portion of the inner pipe with a gap between them; the inner pipe has a porous sintered body for allowing the passage of the gas in at least a part of it; and the outer pipe has a large number of gas outlet ports for discharging the gas having passed through the sintered body surface into the vacuum vessel.

A vacuum processing apparatus according to the invention is provided with a gas supply pipe for supplying a gas into a vacuum vessel for processing a substrate, wherein the gas supply pipe is a double-layer pipe comprising an inner pipe connected to a gas introduction pipe and an outer pipe for covering the outer peripheral portion of the inner pipe with a gap between them; the inner pipe has a porous sintered body for allowing the passage of the gas in at least a part of it; and the outer pipe has a large number of gas outlet ports for discharging the gas having passed through the sintered body into the vacuum vessel.

A method of producing an electronic device according to the invention comprises a step of processing a substrate in a vacuum processing apparatus provided with a gas supply pipe for supplying a gas into a vacuum vessel, wherein the gas supply pipe is a double-layer pipe comprising an inner pipe connected to a gas introduction pipe and an outer pipe for covering the outer peripheral portion of the inner pipe with a gap between them; the inner pipe has a porous sintered body for allowing the passage of the gas in at least a part of it; and the outer pipe has a large number of gas outlet ports for discharging the gas having passed through the sintered body into the vacuum vessel.

### EFFECTS OF THE INVENTION

According to the present invention, the gas supply pipe has a double-layer pipe structure, and the gas is diffused in the outer pipe upon passing through the porous sintered body surface of the inner pipe and discharged from a large number of gas outlet ports of the outer pipe. Therefore, even if the gas supply pipe has a long overall length, the gas can be supplied uniformly, and uniformity in film quality can be secured.

### BRIEF DESCRIPTION OF THE DRAWINGS

FIGS. 1A and 1B are schematic views exemplifying the vacuum processing apparatus of a first embodiment provided with a gas supply device according to the invention.

FIG. 2 is a schematic view showing a structure of the gas supply device of the embodiment.

FIGS. 3A, 3B and 3C are schematic views exemplifying cross section structures of gas supply pipes of the gas supply device.

FIG. 4 is a schematic view exemplifying the vacuum processing apparatus according to a second embodiment.

FIGS. 5A, 5B and 5C are schematic views exemplifying the vacuum processing apparatus according to a third embodiment.

FIG. 6 is a schematic view exemplifying the vacuum processing apparatus according to a fourth embodiment.

FIG. 7 is a schematic view showing a structure of the gas supply device according to another example.

### MODE FOR CARRYING OUT THE INVENTION

Embodiments of the present invention are described below with reference to the drawings, but the present invention is not limited to the embodiments.

### First Embodiment

### <Vacuum Processing Apparatus>

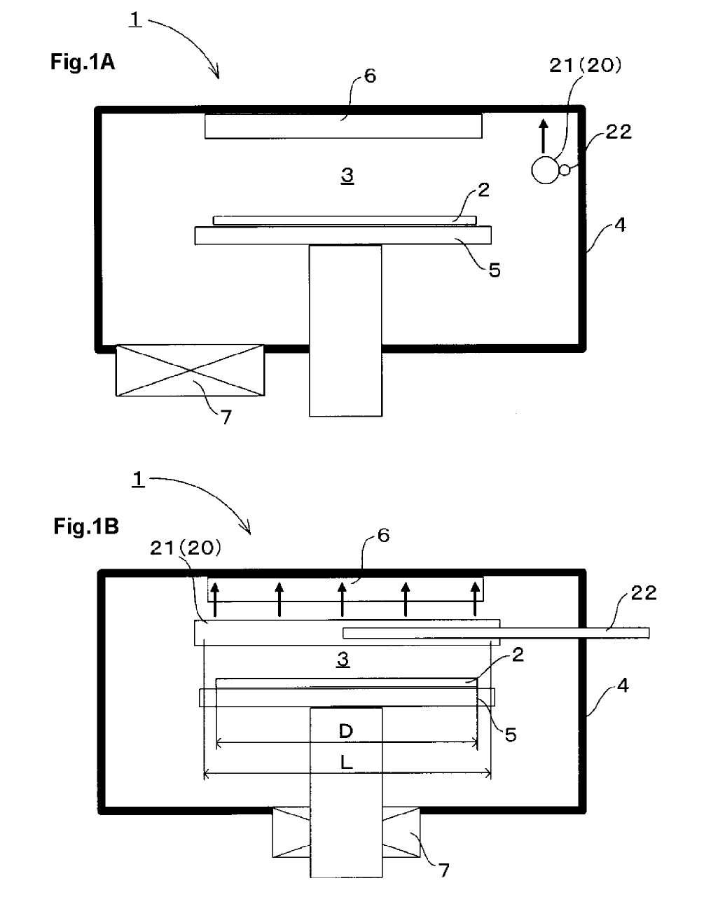

First, a first embodiment of the vacuum processing apparatus according to the invention is described with reference to FIGS. 1A and 1B. FIGS. 1A and 1B show the vacuum processing apparatus of the first embodiment provided with the gas supply device according to the invention, FIG. 1A is a schematic front view, and FIG. 1B is a schematic right side view.

As shown in FIGS. 1A and 1B, a vacuum processing apparatus 1 of this embodiment is provided with a vacuum vessel 4 which defines a processing space 3 for a substrate 2. A substrate support base 5 on which the substrate 2 is placed is provided at the center in the vacuum vessel 4. For example, the substrate support base 5 is constructed such that it supports the substrate 2 on its placing surface by an electrostatic adsorption method and can be rotated and moved vertically.

A cathode unit 6 is disposed on the top in the vacuum vessel 4 in opposite to the substrate support base 5. The cathode unit 6 is provided with a magnet unit which supports a target on the front surface side of a cathode casing and applies a magnetic field to the target on the back surface side. In addition, an exhaust port 7 which is connected to an unshown exhaust system (exhaust pump) is disposed on the bottom of the vacuum vessel 4 to exhaust the vacuum vessel in order to keep it in a vacuum state.

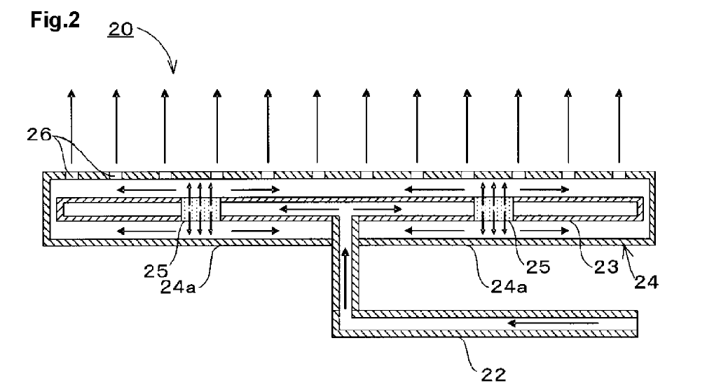

And, a gas supply pipe 21 of a gas supply device 20 to be described later in detail is disposed along a side wall of the vacuum vessel 4 and connected with a gas introduction pipe 22, and a processing gas containing a reactive gas is supplied through gas outlet ports 26 (see FIG. 2) of the gas supply pipe 21 into the vacuum vessel. The gas introduction pipe 22 is connected to a gas introducing system including a gas source.

In this embodiment, the gas outlet ports 26 of the gas supply pipe 21 are formed to face the top wall of the vacuum vessel 4 and directed in the opposite direction from the substrate 4. Therefore, the flow of the gas supplied through the gas outlet ports 26 of the gas supply pipe 21 collides against the top wall surface of the vacuum vessel 2 to move toward the processing space at the center of the vessel, so that the gas flow becomes more uniform.

### <Gas Supply Device>

A specific structure of the gas supply device 20 of this embodiment is described below with reference to FIG. 2. FIG. 2 is a schematic view showing the structure of the gas supply device of this embodiment.

As shown in FIG. 2, the gas supply device 20 is a device provided with the gas supply pipe 21 for supplying the processing gas into the vacuum vessel, and the gas supply pipe 21 is a double-layer pipe comprising an inner pipe 23 connected to the gas introduction pipe 22 and an outer pipe 24 which covers the outer peripheral portion of the inner pipe 23 with a space between them.

The gas introduction pipe 22 is extended from the gas source and connected to a longitudinal center part of the inner pipe 23 through a longitudinal center part of the outer pipe 24. The connection to the center part of the inner pipe 23 as described above is to homogenize the gas discharge amount from the gas supply pipe 21. And, a porous sintered body 25 is partly interposed (intermediate part) in the inner pipe 23 and has a porous sintered body surface which allows the passage of the gas.

The outer pipe 24 is formed with multiple gas outlet ports 26 for flowing the gas, which is introduced from the gas introduction pipe 22 into the inner pipe 23 and passed through the sintered body surface, into the vacuum vessel. The gas outlet ports 26 are formed in a large number in the longitudinal direction of the outer pipe 24 and open to the top wall of the vacuum vessel 2 as described above. And, a formation range L of the gas outlet ports 26 of the outer pipe 24 is set to be larger than a width (outer diameter) D of the substrate 2 which is processed in the vacuum vessel.

To homogenize the gas discharge amount from the outer pipe 24, the sintered body surface of the inner pipe 23 is arranged symmetrically on either side of a width-direction center (radial center) of the substrate 2 and positioned at the center of each of right and left portions 24a and 24a of the outer pipe 24, which are divided at the connection of the gas introduction pipe 22. Here, even if the inner pipe 23 has a length merely enough to the sintered body 25, the gas volume is variable depending on positions within the outer pipe 24, so that it is necessary to extend the outer pipe 24 in order to homogenize the gas discharge amount. Therefore, when the inner pipe 23 is extended more than the sintered body 25 within the outer pipe 24, it is not necessarily required to be hollow.

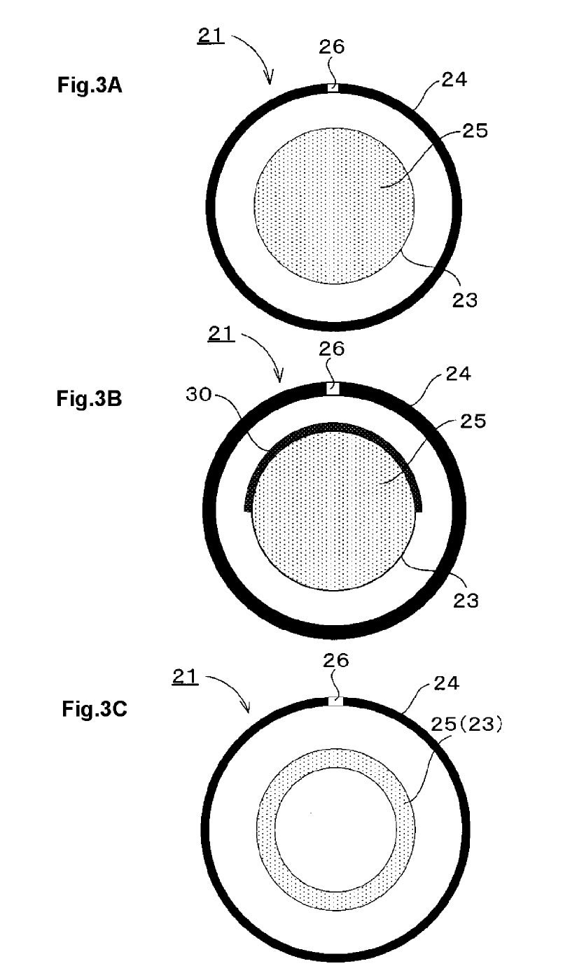

An embodiment of a cross section structure of the above-described gas supply pipe 21 is described below with reference to FIGS. 3A to 3C. FIGS. 3A to 3C are schematic views exemplifying cross section structures of the gas supply pipe 21 of the gas supply device 20.

The gas supply pipe 21 exemplified in FIG. 3A is an example that a cylindrical porous sintered body 25 is interposed at an intermediate part of the inner pipe 23. For the sintered body 25, for example, a metal sintered body obtained by powder metallurgy can be used. As a component metal, it is preferable to use metal such as aluminum or stainless steel (SUS) having heat resistance and corrosion resistance. The sintered body 25 is preferably formed of sintered granules of several micrometers and disposed at the intermediate part of the inner pipe 23 by using a bonding means such as welding such that its pores are not clogged. The outer pipe 24 covers the outer peripheral portion of the inner pipe 23 with an interval between them, and the gas outlet ports 26 are formed in its top.

The gas supply pipe 21 of another embodiment exemplified in FIG. 3B has the upper half surface of a cylindrical sintered body 25 which is interposed at the intermediate part of the inner pipe 23 covered by a cover member 30 having a half-split short tubular shape. The outer pipe 24 covers the outer peripheral portion of the inner pipe 23 with a gap between them, and the gas outlet ports 26 are formed in the top. In other words, the sintered body surface of the inner pipe 23 within the outer pipe 24 is directed in a direction opposite to the formed side of the gas outlet ports 26 of the outer pipe 24. In this embodiment, since the upper half surface of the sintered body 25 is covered by the cover member 30 having a half-split short tubular shape, the gas in the inner pipe 23 is supplied to the sintered body 25 and discharged from the sintered body surface toward a direction opposite to the gas outlet ports 26 formed in the outer pipe 24. Thus, the gas is rectified and readily supplied at a constant flow rate into the vacuum vessel.

The inner pipe itself may be formed of a cylindrical sintered body 25 as in the gas supply pipe 21 according to another embodiment exemplified in FIG. 3C.

Using the gas supply pipes 21 having the structures described above maintain a constant flow rate distribution of the processing gas discharged from the gas outlet ports 26 of the outer pipe 24. It is desirable that the number of the gas outlet ports 26 are larger, but it is normally adequate to have approximately one gas outlet port 26 in each portion at intervals of 50 mm in the longitudinal direction of the outer pipe 24. And, since the external shape of the gas supply pipe 21 is not complex, its installation place is hardly restricted. A method of adjusting the flow rate to the gas introduction pipe 2 is not limited, but it is desirable to control it by a mass flow controller or the like.

As described above, according to the gas supply device 20 of this embodiment, the gas supply pipe 21 has a double-layer pipe structure, and the gas is diffused in the outer pipe 24 upon passing through the porous sintered body surface of the inner pipe 23 and discharged from the large number of gas outlet ports 26 of the outer pipe 24. Therefore, even if the gas supply pipe 21 has a long overall length, the gas can be supplied uniformly, and uniformity in film quality can be secured.

### Second Embodiment

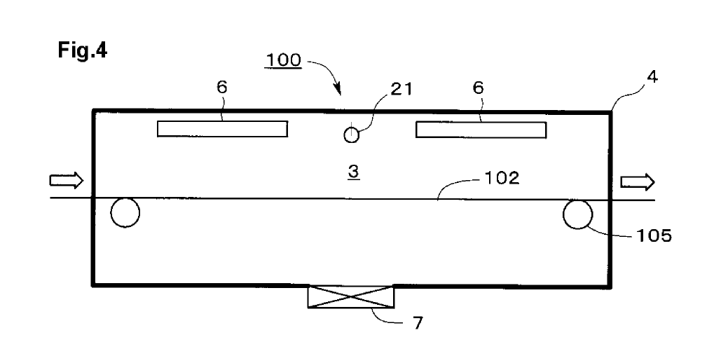

A vacuum processing apparatus 100 of a second embodiment is described below with reference to FIG. 4. FIG. 4 is a schematic sectional view exemplifying the vacuum processing apparatus of the second embodiment. For description, like component members corresponding to those of the first embodiment are denoted by like reference numerals.

As shown in FIG. 4, in the vacuum processing apparatus 100 of the second embodiment, unshown substrate entrance and substrate exit are formed in both sides of the vacuum vessel 4 which defines the processing space 3, and a long substrate (or belt-shaped substrate) 102 is conveyed along rollers 105. The bottom of the vacuum vessel 4 is provided with an exhaust port 7 which is connected to an exhaust system for exhausting the processing space 3.

And, two cathode units 6 are disposed at upper portions in the vacuum vessel 4 in a direction that the long substrate 102 is conveyed, and continuous film forming processing is performed within the vacuum vessel. The gas supply pipe 21 of the above-described gas supply device 20 for supplying a processing gas containing a reactive gas into the vacuum vessel at the time of the film forming processing is disposed between the two cathode units 6. The gas supply pipe 21 is extended along a direction (width direction) intersecting at right angles to the longitudinal direction of the long substrate 102.

The gas supply pipe 21 is formed with the gas outlet ports 26 in the top of the outer pipe 24 and discharges the gas toward the top wall of the vacuum vessel 4 (see FIGS. 3A, 3B and 3C).

The vacuum processing apparatus 100 of the second embodiment can use the gas supply device 20 having the structure described above to maintain a constant flow rate distribution of the processing gas discharged from the gas outlet ports 26 of the gas supply pipe 21. In other words, in the vacuum processing apparatus 100 of the second embodiment, the processing gas supplied from the gas supply device 20 flows without suffering from disturbance of its distribution to the processing space 3 between the target and the long substrate 102.

### Third Embodiment

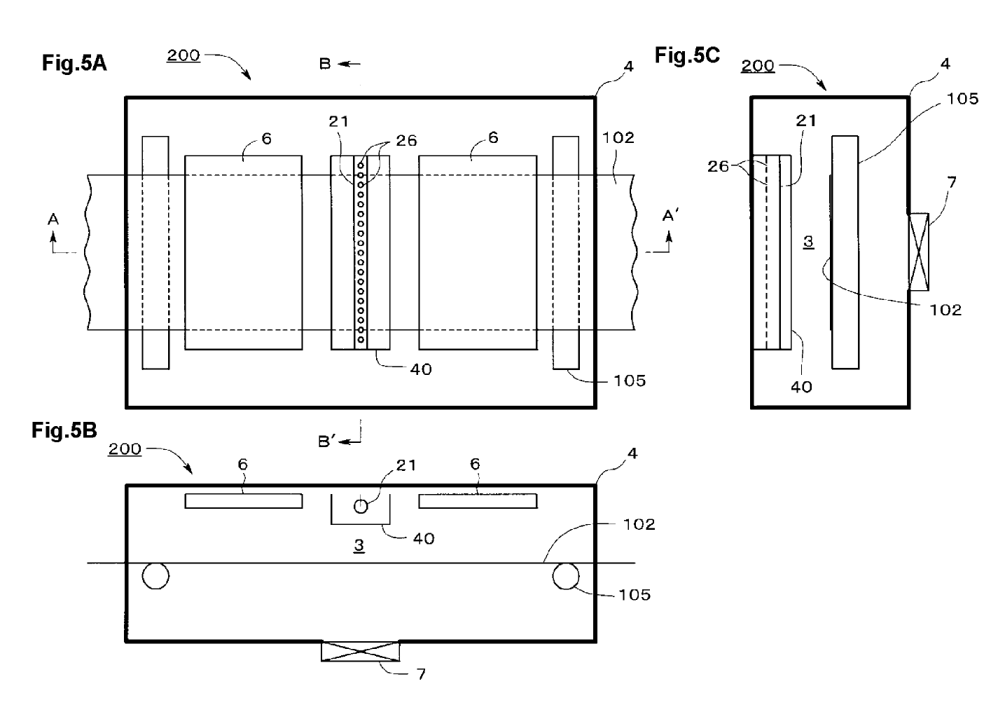

A vacuum processing apparatus 200 of a third embodiment is described below with reference to FIGS. 5A, 5B and 5C.

FIG. 5A is a schematic view of the vacuum processing apparatus of the third embodiment viewed see-through from above. FIG. 5B is a schematic sectional view taken along A-A′ of the vacuum processing apparatus shown in FIG. 5A. FIG. 5C is a schematic sectional view taken along B-B′ of the vacuum processing apparatus shown in FIG. 5A.

The vacuum processing apparatus 200 of the third embodiment has a structure that the gas supply pipe 21 of the second embodiment is further surrounded by a shield 40 having a rectangular box shape. In this embodiment, the gas supply pipe 21 has the gas outlet ports 26 formed in the top of the outer pipe 24 and discharges the gas toward the top wall of the vacuum vessel 4 in the same manner as in the second embodiment. According to this structure, the gas supplied from the gas outlet ports 26 of the gas supply pipe 21 collides against the top wall surface of the vacuum vessel 4 and then against the shield 40, so that the gas is hard to diffuse freely within the vacuum vessel 4.

Among the side walls of the shield 40, a gap is provided between each side wall which extends in a direction (width direction) intersecting at right angles to the longitudinal direction of the long substrate 102 and the top wall surface of the vacuum vessel 4. Meanwhile, no gap is provided between the side walls of the shield 40, which extend in the longitudinal direction (traveling direction of long substrate) of the long substrate 102, and the top wall surface of the vacuum vessel 4. Namely, it is configured such that the gas does not flow out from both width-direction ends of the shield 40.

Thus, the flow of the gas supplied from the gas outlet ports 26 of the gas supply pipe 21 collides against the top wall surface of the vacuum vessel 4 and then introduced into the vacuum vessel 4 from only the gap between the side walls of the shield 40 extended in the width direction of the long substrate 102 and the top wall surface of the vacuum vessel 4. Therefore, the gas flow to only the processing space in the vicinity of the cathode unit 6 becomes more uniform and the gas is supplied there.

Since the gas outlet ports 26 of the gas supply pipe 21 are formed in the top of the outer pipe 24 and discharge the gas toward the top wall of the vacuum vessel 4, the gas flows to the processing space in the vicinity of the two cathode units 6, which are disposed upstream and downstream in a conveying direction of the long substrate 102, become equal to each other.

The gap between the side walls of the shield 40 extended in the width direction of the long substrate 102 and the top wall surface of the vacuum vessel 4 is desirably of a size not larger than the mean free path of gas molecules being supplied. When the gap is not less than the mean free path of the gas molecules, the gas is diffused in the vacuum vessel 4 and cannot be supplied uniformly from the gaps between the top wall surface of the vacuum vessel 4 and the side walls of the shield 40 extended in the width direction of the long substrate 102 into only the processing space in the vicinity of the cathode unit 6.

Since the mean free path of Ar, O2 and N2 is about 6 mm when a processing pressure is 1 Pa, the gaps between the top wall surface of the vacuum vessel 4 and the side walls of the shield 40 extended in the width direction of the long substrate 102 must be made smaller than 6 mm.

### Fourth Embodiment

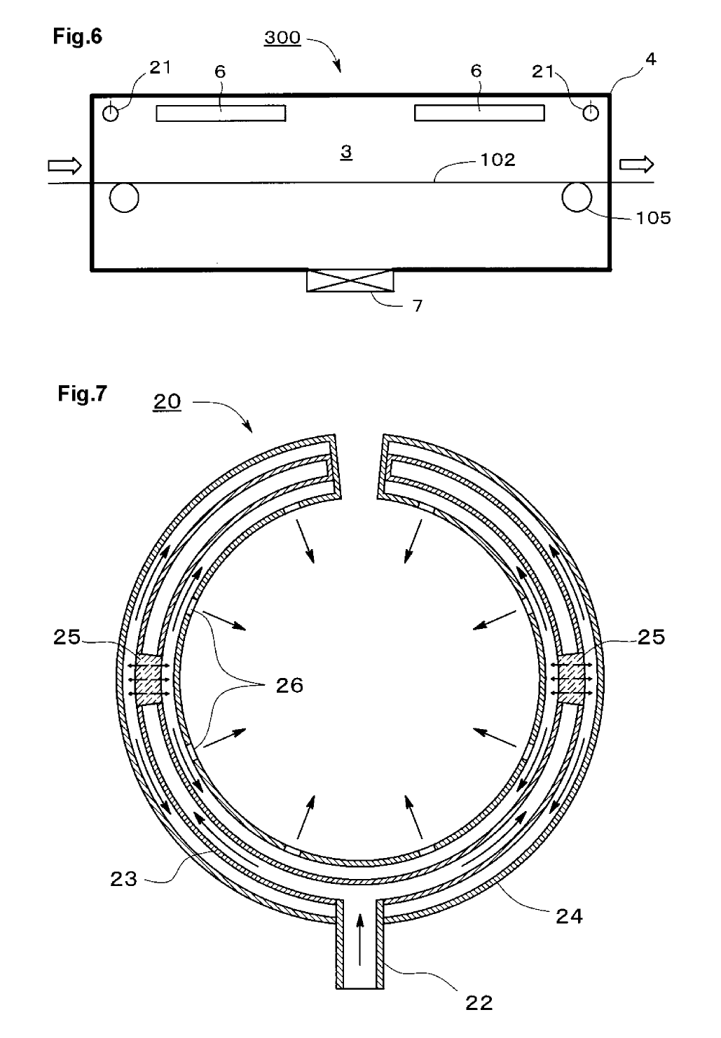

A vacuum processing apparatus 300 of a fourth embodiment is described below with reference to FIG. 6. FIG. 6 is a schematic view exemplifying the vacuum processing apparatus of the fourth embodiment. For description, like component members corresponding to those of the first, second and third embodiments are denoted by like reference numerals.

In the vacuum processing apparatus 300 of the fourth embodiment, the gas supply pipe 21 of the gas supply device 20 is disposed near each end portion of two cathode units 6 on the side of the side wall in the substrate conveying direction. In this embodiment, the gas outlet ports 26 of the gas supply pipe 21 are also formed in the top of the outer pipe 24, and the gas is discharged toward the top wall of the vacuum vessel 4 (see FIG. 4). The discharge direction is not limited to the above, but the gas outlet ports 26 may be formed in the outer pipe 24 to face the direction of each target.

The vacuum processing apparatus 300 of the fourth embodiment can use the gas supply device 20 having the above-described structure to maintain a constant flow rate distribution of the processing gas discharged from the gas outlet ports 26 of the gas supply pipe 21. In other words, in the vacuum processing apparatus 300 of the fourth embodiment, the processing gas supplied from the gas supply device 20 flows without suffering from disturbance of its distribution to the processing space 3 between the targets and the long substrate 102.

Although the invention has been described above by reference to the embodiments of the invention, the invention is not limited to the embodiments described above. It is to be understood that modifications and variations of the embodiments can be made without departing from the spirit and scope of the invention.

### [Another Example of Gas Supply Device]

Another example of the gas supply device 20 is described below with reference to FIG. 7. FIG. 7 is a schematic view showing a structure of the gas supply device according to this example. For description, like component members corresponding to those of the gas supply device 20 of the first embodiment are denoted by like reference numerals.

As shown in FIG. 7, this gas supply device is similar to the gas supply device 20 shown in FIG. 2 and provided with the gas supply pipe 21 having a double-layer pipe structure comprising the inner pipe 23 connected to the gas introduction pipe 22 and the outer pipe 24 which covers the outer peripheral portion of the inner pipe 23 with a gap between them, but the gas supply pipe 21 has a C-shaped circular shape. And, the gas introduction pipe 22 is connected to the center of a curve length of the inner pipe 23 having the same C shape through the center of a curve length of the outer pipe 24 having the same C shape. A large number of gas outlet ports 26 are formed in the outer pipe 24 to flow the gas, which is introduced from the gas introduction pipe 22 to the inner pipe 23 and passed through the porous sintered body 25, into the vacuum vessel. The large number of the gas outlet ports 26 are formed at regular intervals in the inner circumferential surface of the outer pipe 24.

When the gas supply device 20 of this example is disposed between the cathode unit 6 and the substrate 2 shown in, for example, FIG. 1, the gas can be securely supplied to the space between the cathode unit 6 and the substrate.

In this example, the gas outlet ports 26 are formed in the inner circumferential surface of the outer pipe 24, but the gas outlet ports 26 can also be formed in an outer circumferential surface, a top surface or a bottom surface of the outer pipe 24.

For example, the vacuum processing apparatus according to the embodiments of the invention can also be applied to the vacuum processing apparatus which is used in the film forming process for producing an electronic device such as a large flat-panel display (liquid crystal display), a thin-film solar cell panel, a microinductor or a magnetic recording head.

### EXPLANATION OF REFERENCE NUMERALS

1, 100, 200, 300: Vacuum processing apparatus
2, 102: Substrate
3: Processing space
4: Vacuum vessel
5: Substrate support base
6: Cathode unit
7: Exhaust port
20: Gas supply device
21: Gas supply pipe
22: Gas introduction pipe
23: Inner pipe
24: Outer pipe
25: Sintered body
26: Gas outlet ports
30: Cover member
40: Shield

1. A gas supply device provided with a gas supply pipe for supplying a gas into a vacuum vessel, wherein:
the gas supply pipe is a double-layer pipe comprising an inner pipe connected to a gas introduction pipe and an outer pipe for covering the outer peripheral portion of the inner pipe with a gap between them;
the inner pipe has a porous sintered body for allowing the passage of the gas in at least a part of it; and
the outer pipe has a large number of gas outlet ports for discharging the gas having passed through the sintered body into the vacuum vessel.

2. The gas supply device according to claim 1, wherein a range of forming the gas outlet ports of the outer pipe is set to be larger than the width of a substrate processed within the vacuum vessel.

3. The gas supply device according to claim 1, wherein:
the gas introduction pipe is connected to a longitudinal center part of the inner pipe through the center of the outer pipe; and
the sintered body surface of the inner pipe is arranged symmetrically on either side of a width-direction center of the substrate and positioned at the center between right and left portions of the outer pipe which is divided at the connection of the gas introduction pipe.

4. The gas supply device according to claim 1, wherein the sintered body of the inner pipe within the outer pipe is directed in a direction opposite to the formed side of the gas outlet ports of the outer pipe.

5. A vacuum processing apparatus provided with a gas supply pipe for supplying a gas into a vacuum vessel for processing a substrate, wherein:
the gas supply pipe is a double-layer pipe comprising an inner pipe connected to a gas introduction pipe and an outer pipe for covering the outer peripheral portion of the inner pipe with a gap between them;
the inner pipe has a porous sintered body for allowing the passage of the gas in at least a part of it; and
the outer pipe has a large number of gas outlet ports for discharging the gas having passed through the sintered body into the vacuum vessel.

6. The vacuum processing apparatus according to claim 5, wherein a target is arranged at a position in opposite to the substrate.

7. The vacuum processing apparatus according to claim 5, wherein the gas is a processing gas.

8. The vacuum processing apparatus according to claim 5, wherein a range of forming the gas outlet ports of the outer pipe is set to be larger than the width of the substrate processed within the vacuum vessel.

9. The vacuum processing apparatus according to claim 5, wherein:
the gas introduction pipe is connected to a longitudinal center part of the inner pipe through the center of the outer pipe; and
the sintered body surface of the inner pipe is arranged symmetrically on either side of a width-direction center of the substrate and positioned at the center between right and left portions of the outer pipe which is divided at the connection of the gas introduction pipe.

10. The vacuum processing apparatus according to claim 5, wherein the sintered body of the inner pipe within the outer pipe is directed in a direction opposite to the formed side of the gas outlet ports of the outer pipe.

11. The vacuum processing apparatus according to claim 6, wherein the target is fixed to a top wall of the vacuum processing apparatus, and the outer pipe gas outlet ports are arranged to discharge the gas toward the top wall of the vacuum processing apparatus.

12. A method of producing a device, comprising a step of processing a substrate in a vacuum processing apparatus provided with a gas supply pipe for supplying a gas into a vacuum vessel, wherein:
the gas supply pipe is a double-layer pipe comprising an inner pipe connected to a gas introduction pipe and an outer pipe for covering the outer peripheral portion of the inner pipe with a gap between them;
the inner pipe has a porous sintered body for allowing the passage of the gas in at least a part of it; and
the outer pipe has a large number of gas outlet ports for discharging the gas having passed through the sintered body into the vacuum vessel.
